(19) United States
(12) Patent Application Publication
(10) Pub. No.: US 2025/0241179 A1
(43) Pub. Date: Jul. 24, 2025

(54) DISPLAY PANEL AND MANUFACTURING METHOD THEREFOR, AND DISPLAY APPARATUS

(71) Applicant: BOE Technology Group Co., Ltd., Beijing (CN)

(72) Inventors: Wei QUAN, Beijing (CN); Juanjuan YOU, Beijing (CN); Changyen WU, Beijing (CN); Cheng XU, Beijing (CN); Dandan ZHOU, Beijing (CN)

(21) Appl. No.: 18/698,003

(22) PCT Filed: Jul. 28, 2023
(86) PCT No.: PCT/CN2023/109999

§ 371 Date: Apr. 2, 2024

(30) Foreign Application Priority Data
Aug. 9, 2022 (CN) 202210950938.4

(51) Int. Cl. H10K 59/80; H10K 59/12; H10K 59/121

(52) U.S. Cl. CPC H10K 59/879; H10K 59/1201; H10K 59/1213; H10K 59/877

(57) ABSTRACT

Disclosed are a display panel and a manufacturing method therefor, and a display apparatus. The display panel includes: a base substrate; a plurality of light-emitting devices, located at one side of the base substrate, where the surfaces of the light-emitting devices facing the base substrate are light-emitting surfaces of the light-emitting devices; and a driving circuit layer, located between the base substrate and the light-emitting devices, where in a region corresponding to a light-emitting region of the light-emitting device, the driving circuit layer includes a light-transmitting portion, the light-transmitting portion includes a low-refractive-index light-transmitting insulating layer and a high-refractive-index light-transmitting insulating layer that are alternately stacked, and the refractive index of the low-refractive-index light-transmitting insulating layer is smaller than that of the high-refractive-index light-transmitting insulating layer.

### CROSS REFERENCE TO RELATED APPLICATIONS

The present application is a National Stage of International Application No. PCT/CN2023/109999, filed on Jul. 28, 2023, which claims priority to Chinese patent application No. 202210950938.4, filed with the China National Intellectual Property Administration on Aug. 9, 2022, and entitled “Display Panel and Manufacturing Method Therefor, and Display apparatus”, which is hereby incorporated by reference in its entirety.

### TECHNICAL FIELD

The present disclosure relates to the field of display technology, and in particular to a display panel and a manufacturing method therefor, and a display apparatus.

### BACKGROUND

Organic light-emitting diodes (OLED) devices have the advantages of self-illumination, wide viewing angle, and high contrast, etc. They are widely used in smart products such as mobile phones, TVs, and laptops. Due to their light weight and thin thickness, and bending resistance, they are currently the research focus of many scholars at home and abroad.

In the prior art, the light exiting path of bottom-emitting OLED devices requires passing through multiple film layers, resulting in significant light transmission loss and low luminous efficiency of bottom-emitting OLED display products.

### SUMMARY

Embodiments of the present disclosure provide a display panel, including: a base substrate; a plurality of light-emitting devices on a side of the base substrate; where a surface of the light-emitting device facing the base substrate is a light exiting surface of the light-emitting device; and a driving circuit layer between the base substrate and the light-emitting devices. In an area corresponding to a light-emitting area of the light-emitting device, the driving circuit layer includes: a light-transmitting portion; the light-transmitting portion includes a low-refractive-index light-transmitting insulating layer and a high-refractive-index light-transmitting insulating layer that are alternately stacked; and a refractive index of the low-refractive-index light-transmitting insulating layer is smaller than a refractive index of the high-refractive-index light-transmitting insulating layer.

In some embodiments, a difference between the refractive indexes of the low-refractive-index light-transmitting insulating layer and the high-refractive-index light-transmitting insulating layer which are adjacent is greater than 0.2.

In some embodiments, the base substrate is adjacent to the low-refractive-index light-transmitting insulating layer; and a refractive index of the low-refractive-index light-transmitting insulating layer adjacent to the base substrate is smaller than a refractive index of the base substrate.

In some embodiments, the driving circuit layer further includes: thin film transistors; and the thin film transistor includes: a gate electrode, and a source electrode and a drain electrode on a side of the gate electrode facing away from the base substrate. The light-transmitting portion includes: a buffer layer between the base substrate and the gate electrode; a first insulating layer between the gate electrode and the source electrode; and a second insulating layer on a side, facing away from the base substrate, of the source electrode and the drain electrode. A refractive index of the first insulating layer is greater than a refractive index of the buffer layer, and the refractive index of the first insulating layer is greater than a refractive index of the second insulating layer.

In some embodiments, the refractive index of the buffer layer is equal to the refractive index of the second insulating layer.

In some embodiments, a thickness of the first insulating layer is greater than a thickness of the buffer layer; and the thickness of the first insulating layer is greater than a thickness of the second insulating layer.

In some embodiments, the thickness of the buffer layer is equal to the thickness of the second insulating layer.

In some embodiments, the first insulating layer, the buffer layer and the second insulating layer include the same material.

In some embodiments, the base substrate further includes: a planarization layer between the light-emitting devices and the driving circuit layer; and the planarization layer includes: a light-transmitting material, and scattering particles dispersed in the light-transmitting material.

In some embodiments, a mass fraction of the scattering particles is greater than or equal to 5% and less than or equal to 10%.

Embodiments of the present disclosure provide a method for manufacturing a display panel, including: forming a driving circuit layer on a side of the base substrate; where the driving circuit layer includes: a light-transmitting portion; the light-transmitting portion includes a low-refractive-index light-transmitting insulating layer and a high-refractive-index light-transmitting insulating layer that are alternately stacked; and a refractive index of the low-refractive-index light-transmitting insulating layer is smaller than a refractive index of the high-refractive-index light-transmitting insulating layer; and forming a plurality of light-emitting devices on a side of the driving circuit layer facing away from the base substrate; where a surface of the light-emitting device facing the base substrate is a light exiting surface of the light-emitting device; and the light-transmitting portion corresponds to a light-emitting area of the light-emitting device.

In some embodiments, the forming the driving circuit layer on the side of the base substrate, specifically includes: forming a buffer layer on a side of the base substrate; where a refractive index of the buffer layer is smaller than a refractive index of the base substrate; forming a first insulating layer on a side of the buffer layer facing away from the base substrate; where a refractive index of the first insulating layer is greater than the refractive index of the buffer layer; and forming a second insulating layer on a side of the first insulating layer facing away from the base substrate; where a refractive index of the second insulating layer is smaller than the refractive index of the first insulating layer.

In some embodiments, the forming a buffer layer on the side of the base substrate, specifically includes: forming silicon oxide as the buffer layer on the side of the base substrate by using a chemical vapor deposition process under the condition that a ratio of silane to nitrous oxide is a first preset ratio. The forming the first insulating layer on the side of the buffer layer facing away from the base substrate, specifically includes: forming silicon oxide as the first insulating layer on the side of the buffer layer facing away from the base substrate by using the chemical vapor deposition process under the condition that a ratio of silane to nitrous oxide is a second preset ratio; where the first preset ratio is greater than the second preset ratio. The forming the second insulating layer on the side of the first insulating layer facing away from the base substrate, specifically includes: forming silicon oxide as the second insulating layer on the side of the first insulating layer facing away from the base substrate by using the chemical vapor deposition process under the condition that the ratio of silane to nitrous oxide is the first preset ratio.

In some embodiments, before forming the plurality of light-emitting devices, the method further includes: forming a planarization layer on the side of the driving circuit layer facing away from the base substrate. The planarization layer includes: a light-transmitting material, and scattering particles dispersed in the light-transmitting material.

Embodiments of the present disclosure provide a display apparatus including the display panel provided by embodiments of the present disclosure.

### BRIEF DESCRIPTION OF FIGURES

In order to more clearly illustrate the technical solutions in embodiments of the present disclosure, a brief introduction will be given below to the drawings needed to be used in the description of embodiments. Obviously, the drawings in the following description are only some embodiments of the present disclosure. Those of ordinary skill in the art can also obtain other drawings based on these drawings without exerting creative efforts.

FIG. 1 is a schematic structural diagram of a display panel provided by embodiments of the present disclosure.

FIG. 2 is another schematic structural diagram of a display panel provided by embodiments of the present disclosure.

FIG. 3 is another schematic structural diagram of a display panel provided by embodiments of the present disclosure.

FIG. 4 is a schematic flowchart of a method for manufacturing a display panel provided by embodiments of the present disclosure.

### DETAILED DESCRIPTION

In order to make the purpose, technical solutions and advantages of embodiments of the present disclosure more clear, the technical solutions of the embodiments of the present disclosure will be clearly and completely described below in conjunction with the drawings of embodiments of the present disclosure. Obviously, the described embodiments are some, but not all, of the embodiments of the present disclosure. And the embodiments and features in the embodiments of the present disclosure may be combined with each other without conflict. Based on the described embodiments of the present disclosure, all other embodiments obtained by those of ordinary skill in the art without creative efforts fall within the scope of the present disclosure.

Unless otherwise defined, technical terms or scientific terms used in this disclosure shall have the usual meaning understood by a person with ordinary skill in the art to which this disclosure belongs. Words such as “first”, “second” used in the disclosure do not indicate any order, quantity or importance, but are only used to distinguish different components. Words such as “including” or “comprising” mean that the component or object that appears before the word includes those listed after the word and their equivalents, without excluding other components or objects. Words such as “connected” or “coupled” are not limited to physical or mechanical connections, but may include electrical connections, whether direct or indirect.

It should be noted that the sizes and shapes of the figures in the drawings do not reflect true proportions and are only intended to illustrate the present disclosure. And, the same or similar reference numbers throughout represent the same or similar components or elements having the same or similar functions.

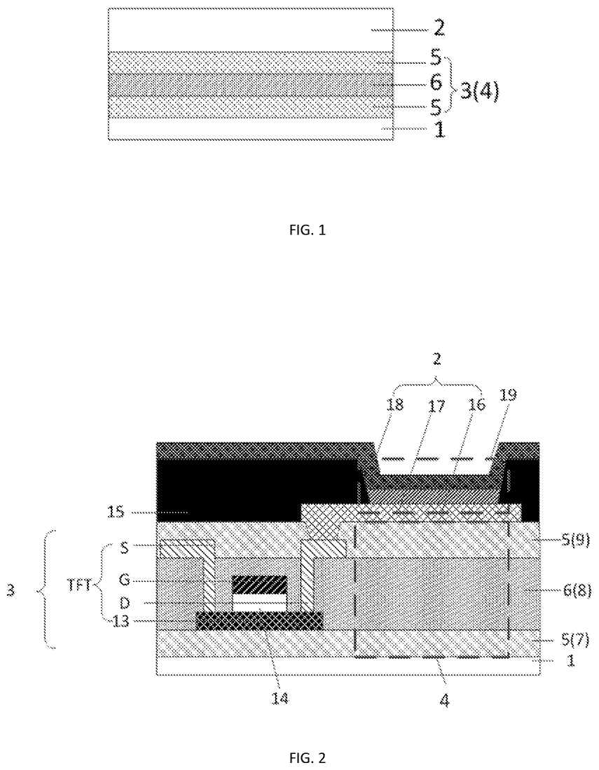

Embodiments of the present disclosure provide a display panel, and as shown in FIG. 1, the display panel includes:
a base substrate 1;
a plurality of light-emitting devices 2 on a side of the base substrate 1; where a surface of the light-emitting device 2 facing the base substrate 1 is a light exiting surface of the light-emitting device 2; and
a driving circuit layer 3 between the base substrate 1 and the light-emitting devices 2; where, in an area corresponding to a light-emitting area of the light-emitting devices 2, the driving circuit layer 3 includes: a light-transmitting portion 4; the light-transmitting portion 4 includes a low-refractive-index light-transmitting insulating layer 5 and a high-refractive-index light-transmitting insulating layer 6 that are alternately stacked; and a refractive index of the low-refractive-index light-transmitting insulating layer 5 is smaller than a refractive index of the high-refractive-index light-transmitting insulating layer 6.

In the display panel provided by embodiments of the present disclosure, the light-transmitting portion includes the low-refractive-index light-transmitting insulating layers and the high-refractive-index light-transmitting insulating layers that are alternately stacked, that is, the light-transmitting portion includes a distributed Bragg reflection (DBR) structure. Light interferes at the interface between the low-refractive-index light-transmitting insulating layer and the high-refractive-index light-transmitting insulating layer, thereby increasing the transmittance of light in a specific wavelength range. That is, by setting the refractive indexes of the low-refractive-index light-transmitting insulating layer and the high-refractive-index light-transmitting insulating layer, the light transmittance of the light-transmitting portion can be increased, thereby improving the luminous efficiency of the display panel.

In some embodiments, the difference between the refractive indexes of the low-refractive-index light-transmitting insulating layer 5 and the high-refractive-index light-transmitting insulating layer 6 which are adjacent is greater than 0.2. Thus, it is more conducive to the interference of light at the interface between the low-refractive-index light-transmitting insulating layer and the high-refractive-index light-transmitting insulating layer, which is more conducive to improving the transmittance of light.

In some embodiments, the base substrate 1 is adjacent to the low-refractive-index light-transmitting insulating layer 5, and the refractive index of the low-refractive-index light-transmitting insulating layer 5 adjacent to the base substrate 1 is less than the refractive index of the base substrate 1. This can avoid the inability of light to emit from the base substrate due to total reflection occurring at the interface between the base substrate and the light-transmitting portion.

In some embodiments, the base substrate is a glass substrate, and the refractive index of the glass substrate is about 1.5, so the refractive index of the low-refractive-index light-transmitting insulating layer adjacent to the glass substrate is less than 1.5.

In specific implementation, the number of low-refractive-index light-transmitting insulating layers and the number of high-refractive-index light-transmitting insulating layers included in the light-transmitting portion may be the same or different, and as long as the low-refractive-index light-transmitting insulating layers and the high-refractive-index light-transmitting insulating layers are alternately arranged, a distributed Bragg reflection structure can be formed. When the light-transmitting portion includes multiple low-refractive-index light-transmitting insulating layers, the refractive indexes of the multiple low-refractive-index light-transmitting insulating layers may all be the same; or the refractive indexes of the multiple low-refractive-index light-transmitting insulating layers may not be completely the same; or the refractive indexes of the multiple low-refractive-index light-transmitting insulating layers may all be different. When the light-transmitting portion includes multiple high-refractive-index light-transmitting insulating layers, the refractive indexes of the multiple high-refractive-index light-transmitting insulating layers may all be the same, or the refractive indexes of the multiple high-refractive-index light-transmitting insulating layers may not be completely the same; or the refractive indexes of the multiple high-refractive-index light-transmitting insulating layers may all be different.

In some embodiments, as shown in FIG. 2, the driving circuit layer 3 further includes: thin film transistors TFT. The thin film transistor TFT includes: a gate electrode G, and a source electrode S and a drain electrode D located on a side of the gate electrode G facing away from the base substrate 1. The light-transmitting portion 4 includes: a buffer layer 7 between the base substrate 1 and the gate electrode G; a first insulating layer 8 between the gate electrode G and the source electrode S; and a second insulating layer 9 on a side, facing away from the base substrate 1, of the source electrode S and the drain electrode D. The refractive index of the first insulating layer 8 is greater than the refractive index of the buffer layer 7, and the refractive index of the first insulating layer 8 is greater than the refractive index of the second insulating layer 9.

As shown in FIG. 2, a portion of the first insulating layer 8 extending to the area corresponding to the light-emitting area of the light-emitting device 2 serves as the high-refractive-index light-transmitting insulating layer 6 in the light-transmitting portion; and a portion of the buffer layer 7 and the second insulating layer 9 extending to the area corresponding to the light-emitting area of the light-emitting device 2 serves as the low-refractive-index light-transmitting insulating layer 5 in the light-transmitting portion. Two low-refractive-index light-transmitting insulating layers 5 and one high-refractive-index light-transmitting insulating layer 6 are alternately arranged.

In some embodiments, the refractive index of the buffer layer 7 is equal to the refractive index of the second insulating layer 9.

When the light-transmitting portion includes multiple low-refractive-index light-transmitting insulating layers, the refractive indexes of the multiple low-refractive-index light-transmitting insulating layers are equal to simplify the design difficulty of the light-transmitting portion.

In specific implementation, for example, the refractive index of the buffer layer and the refractive index of the second insulating layer are approximately 1.47, and the refractive index of the first insulating layer is approximately 1.69.

In some embodiments, the thickness of the first insulating layer 8 is greater than the thickness of the buffer layer 7, and the thickness of the first insulating layer 8 is greater than the thickness of the second insulating layer 9.

That is, the thickness of the high-refractive-index light-transmitting insulating layer is greater than the thickness of the low-refractive-index light-transmitting insulating layer, which is more conducive to light interference at the interface between the low-refractive-index light-transmitting insulating layer and the high-refractive-index light-transmitting insulating layer, and is more conducive to improving the light transmittance. Moreover, the high-refractive-index light-transmitting insulating layer is the first insulating layer located between the gate electrode and the source-drain electrodes, and is thicker to ensure the required performance of the thin film transistor.

In some embodiments, the thickness of the first insulating layer is greater than or equal to 750 nm and less than or equal to 850 nm, and the thickness of the buffer layer and the thickness of the second insulating layer are greater than or equal to 250 nm and less than or equal to 350 nm.

In some embodiments, the thickness of the buffer layer 7 is equal to the thickness of second insulating layer 9.

In some embodiments, the first insulating layer, the buffer layer and the second insulating layer include the same material.

In specific implementation, the first insulating layer, the buffer layer and the second insulating layer all include silicon oxide (SiOₓ).

In some embodiments, the thin film transistor further includes: an active layer. As shown in FIG. 2, the active layer 13 is located between the buffer layer 7 and the gate electrode G. The driving circuit layer 3 further includes a gate insulation layer 14 located between the gate electrode G and the active layer 13. The first insulating layer 8 is an interlayer insulating layer between the gate electrode G, and the source electrode S and the drain electrode D. For example, the second insulating layer 9 is a passivation layer. In FIG. 2, the gate insulating layer 14 is a patterned film layer and does not extend to the light-transmitting area of the light-emitting device 2.

It should be noted that FIG. 2 is illustrated by an example of a thin film transistor with a top-gate structure. Of course, during specific implementation, the thin film transistor may also be a bottom-gate structure, that is, the active layer is located between the gate electrode and the source-drain electrodes. When the thin film transistor is a bottom-gate structure, for example, the first insulating layer is the gate insulating layer located between the active layer and the gate electrode.

In some embodiments, for example, the electroluminescent device is an organic light-emitting diode (OLED). Alternatively, the electroluminescent device may also be a micro light-emitting diode (Micro LED), a mini light-emitting diode (Mini LED), or other light-emitting devices. In the following, the light-emitting device being an OLED is taken as an example to illustrate in the embodiments of the disclosure.

In some embodiments, as shown in FIG. 2, the light-emitting device 2 includes: an anode 16, a light-emitting functional layer 17, and a cathode 18. The anode 16 is electrically connected with the drain electrode D of the thin film transistor TFT through a via hole penetrating the second insulating layer 9. The display panel further includes a pixel definition layer 15, and the pixel definition layer 15 has a plurality of opening areas 19 which are in one-to-one correspondence with the light-emitting devices 2. The opening area 19 exposes part of the anode 16, and the pixel definition layer 15 covers the edge of the anode 16. The anode 16, the light-emitting functional layer 17, and the cathode 18 are stacked in the opening area 19.

In some embodiments, the cathodes of multiple light-emitting devices may be integrally connected.

In some embodiments, the light-emitting functional layer includes an organic light-emitting layer, and may further include an electron injection layer, an electron transport layer, a hole transport layer, a hole injection layer, etc.

It should be noted that the surface of the light-emitting device facing the base substrate is the light exiting surface, that is, the light-emitting device is a bottom-emitting device. Bottom-emitting devices can achieve total reflection of the light path at the cathode and improve the light extraction efficiency of the light-emitting devices. When the light-emitting device includes an anode, a light-emitting functional layer, and a cathode which are stacked in the opening area, the cathode can be a thick metal layer. For example, the material of the cathode includes silver or aluminum. For example, the thickness of the cathode is greater than or equal to 800 angstroms and less than or equal to 1200 angstroms. For example, the anode may include indium tin oxide (ITO), and the thickness of the anode may be 1000 angstroms.

In some embodiments, an orthographic projection of the light-emitting area of the light-emitting device on the base substrate falls within an orthographic projection of the light-transmitting portion on the base substrate. In specific implementation, the light-emitting area of the light-emitting device is the area corresponding to the opening area of the pixel definition layer.

In some embodiments, the refractive indexes and thicknesses of the same film layers in different light-transmitting portions corresponding to different light-emitting devices are the same. For example, in areas corresponding to different light-emitting devices, the refractive indexes of the buffer layers are the same and the thicknesses of the buffer layers are also the same. In areas corresponding to different light-emitting devices, the refractive indexes of the first insulating layers are the same and the thicknesses of the first insulating layers are also the same. In the areas corresponding to different light-emitting devices, the refractive indexes of the second insulating layers are the same, and the thicknesses of the second insulating layers are also the same.

In specific implementation, the display panel has a plurality of sub-pixels. For example, each sub-pixel corresponds to one light-emitting device, and the light-emitting area of the light-emitting device is the light-emitting area of the sub-pixel. For example, the plurality of sub-pixels include a plurality of red sub-pixels, a plurality of blue sub-pixels and a plurality of green sub-pixels.

In some embodiments, the plurality of light-emitting devices all emit the same color. When the same film layers in the different light-transmitting portions corresponding to different light-emitting devices have the same refractive index and the same thickness, the area corresponding to the light-emitting area of each light-emitting device can improve light transmittance.

In specific implementation, when the luminous colors of the plurality of light-emitting devices are all the same, the color conversion layer can be used to emit red light, green light, and blue light. For example, a quantum dot color film can be provided on a side of the base substrate facing away from the light-emitting devices for color conversion. If the light-emitting devices emit white light, the color conversion layer needs to be provided in the area corresponding to each sub-pixel area. If the light-emitting devices emit blue light, it is only necessary to provide the color conversion layer in the areas corresponding to the red sub-pixels and green sub-pixels.

Alternatively, in specific implementation, the plurality of light-emitting devices include: a plurality of red light-emitting devices, a plurality of blue light-emitting devices, and a plurality of green light-emitting devices. Under the condition that the refractive index and thickness of the same film layers are the same in different light-transmitting portions corresponding to different light-emitting devices, when designing the refractive indexes and thicknesses of the low-refractive-index light-transmitting insulating layer and the high-refractive-index light-transmitting insulating layer included in the light-transmitting portion, it can be considered to increase the light transmittance of at least one type of light-emitting devices. In the case of improving the light transmittance of the display panel, the luminous efficiency between different sub-pixels can also be balanced.

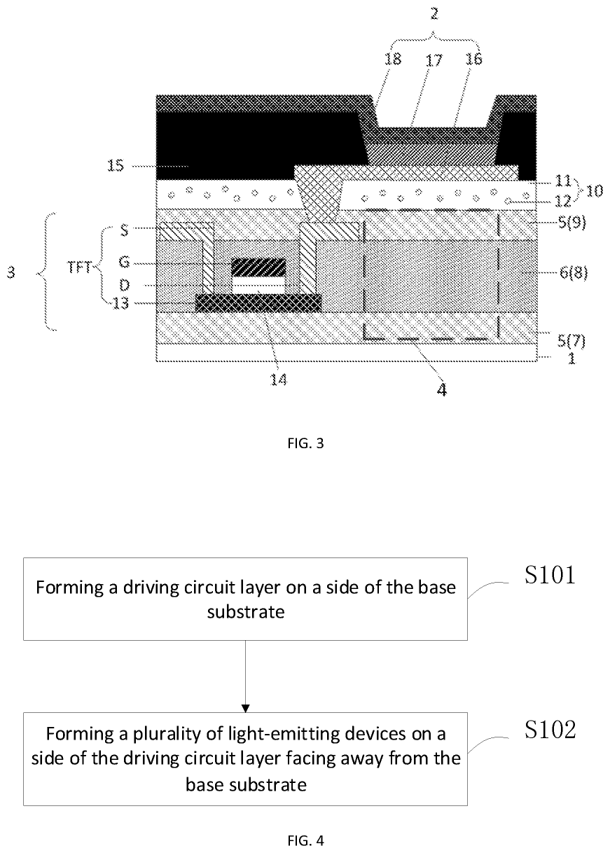

In some embodiments, as shown in FIG. 3, the base substrate 1 further includes: a planarization layer 10 between the light-emitting devices 2 and the driving circuit layer 3. The planarization layer 10 includes: a light-transmitting material 11, and scattering particles 12 dispersed in the light-transmitting material 11.

In the display panel provided by embodiments of the present disclosure, the planarization layer located between the light-emitting devices and the driving circuit layer includes scattering particles, thereby reducing the total reflection of the light emitted by the light-emitting device between the planarization layer and the light-transmitting portion, further improving the light extraction efficiency of the light-emitting device.

In specific implementation, as shown in FIG. 3, the anode 16 is electrically connected with the drain electrode D of the thin film transistor TFT through a via hole penetrating the planarization layer 10 and the second insulating layer 9.

In some embodiments, the light-transmitting material included in the planarization layer is resin.

In some embodiments, the material of the scattering particles is zirconium oxide (ZrO₂).

In some embodiments, the mass fraction of the scattering particles is greater than or equal to 5% and less than or equal to 10%.

In some embodiments, the refractive index of scattered particles is approximately 2.

In some embodiments, the thickness of the planarization layer is greater than or equal to 1 micron and less than or equal to 2 microns.

Based on the same inventive concept, embodiments of the present disclosure further provide a method for manufacturing a display panel, as shown in FIG. 4, including:
S101, forming a driving circuit layer on a side of the base substrate; where the driving circuit layer includes: a light-transmitting portion; the light-transmitting portion includes a low-refractive-index light-transmitting insulating layer and a high-refractive-index light-transmitting insulating layer that are alternately stacked; and a refractive index of the low-refractive-index light-transmitting insulating layer is smaller than a refractive index of the high-refractive-index light-transmitting insulating layer; and
S102, forming a plurality of light-emitting devices on a side of the driving circuit layer facing away from the base substrate; where a surface of the light-emitting device facing the base substrate is a light exiting surface of the light-emitting device; and the light-transmitting portion corresponds to a light-emitting area of the light-emitting device.

In the manufacturing method of a display panel provided by embodiments of the present disclosure, the light-transmitting portion of the formed driving circuit layer includes the low-refractive-index light-transmitting insulating layer and the high-refractive-index light-transmitting insulating layer that are alternately stacked, that is, the light-transmitting portion includes a distributed Bragg reflection structure. Light interferes at the interface between the low-refractive-index light-transmitting insulating layer and the high-refractive-index light-transmitting insulating layer, thereby increasing the transmittance of light in a specific wavelength range. That is, by setting the refractive indexes of the low-refractive-index light-transmitting insulating layer and the high-refractive-index light-transmitting insulating layer, the light transmittance of the light-transmitting portion can be increased, thereby improving the luminous efficiency of the display panel.

In some embodiments, forming the driving circuit layer on a side of the base substrate, specifically includes:
forming a buffer layer on a side of the base substrate; where a refractive index of the buffer layer is smaller than a refractive index of the base substrate;
forming a first insulating layer on a side of the buffer layer facing away from the base substrate; where a refractive index of the first insulating layer is greater than the refractive index of the buffer layer; and
forming a second insulating layer on a side of the first insulating layer facing away from the base substrate; where a refractive index of the second insulating layer is smaller than the refractive index of the first insulating layer.

In some embodiments, before forming the first insulating layer on the side of the buffer layer facing away from the base substrate, the method further includes:
forming a pattern of the active layer on a side of the buffer layer facing away from the base substrate;
forming a pattern of the gate insulating layer on a side of the active layer facing away from the base substrate; and
forming a pattern of a gate electrode on a side of the gate insulating layer facing away from the base substrate.

In some embodiments, after forming the first insulating layer on the side of the buffer layer facing away from the base substrate, and before forming the second insulating layer on the side of the first insulating layer facing away from the base substrate, the method further includes:
forming patterns of a source electrode and a drain electrode on the side of the buffer layer facing away from the base substrate.

In some embodiments, forming the buffer layer on a side of the base substrate, specifically includes:
forming silicon oxide as the buffer layer on the side of the base substrate by using a chemical vapor deposition process under the condition that a ratio of silane to nitrous oxide is a first preset ratio.

Forming the first insulating layer on the side of the buffer layer facing away from the base substrate, specifically includes:
forming silicon oxide as the first insulating layer on the side of the buffer layer facing away from the base substrate by using the chemical vapor deposition process under the condition that a ratio of silane to nitrous oxide is a second preset ratio; where the first preset ratio is greater than the second preset ratio.

Forming the second insulating layer on the side of the first insulating layer facing away from the base substrate, specifically includes:
forming silicon oxide as the second insulating layer on the side of the first insulating layer facing away from the base substrate by using the chemical vapor deposition process under the condition that the ratio of silane to nitrous oxide is the first preset ratio.

During specific implementation, the second preset ratio is smaller than the first preset ratio, so that the refractive index of the silicon oxide layer formed by the second preset ratio is greater than the refractive index of the silicon oxide layer formed by the first preset ratio.

In the method for manufacturing the display panel provided by embodiments of the present disclosure, when the materials of the film layers included in the light-transmitting portion are the same and all include silicon oxide, by adjusting the ratio of silane to nitrous oxide in the vapor deposition process, the refractive indexes of the formed silicon oxide layers can be adjusted. The process is simple and easy to implement, and it can also simplify the design and preparation difficulty of display panels.

In specific implementation, for example, taking the refractive index of the buffer layer and the refractive index of the second insulation layer as approximately 1.47 and the refractive index of the first insulation layer as approximately 1.69, the first preset ratio is approximately 1:5 and the second preset ratio is approximately 1:30.

In some embodiments, before forming the plurality of light-emitting devices, the method further includes: forming a planarization layer on the side of the driving circuit layer facing away from the base substrate. The planarization layer includes: a light-transmitting material, and scattering particles dispersed in the light-transmitting material.

In specific implementation, for example, the scattering particles are mixed with resin, and the material mixed with the scattering particles and resin is coated on the side of the driving circuit layer facing away from the base substrate to form the planarization layer.

Embodiments of the present disclosure provide a display apparatus, including the display panel provided by embodiments of the present disclosure.

The display apparatus provided by embodiments of the present disclosure can be: a mobile phone, a tablet computer, a television, a monitor, a notebook computer, a digital photo frame, a navigator, or any other product or component with a display function. Other essential components of the display apparatus should be understood by those of ordinary skill in the art, and will not be described in detail here, nor should they be used to limit the present disclosure. The implementation of this display apparatus can be found in the above embodiments of the display panel, and any repetition will not be repeated.

To sum up, in the display panel and the manufacturing method therefor, and the display apparatus provided by embodiments of the present disclosure, the light-transmitting portion includes the low-refractive-index light-transmitting insulating layer and the high-refractive-index light-transmitting insulating layer that are alternately stacked, that is, the light-transmitting portion includes a distributed Bragg reflection structure. Light interferes at the interface between the low-refractive-index light-transmitting insulating layer and the high-refractive-index light-transmitting insulating layer, thereby increasing the transmittance of light in a specific wavelength range. That is, by setting the refractive indexes of the low-refractive-index light-transmitting insulating layer and the high-refractive-index light-transmitting insulating layer, the light transmittance of the light-transmitting portion can be increased, thereby improving the luminous efficiency of the display panel.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the disclosure.

Evidently, those skilled in the art can make various modifications and variations to the present disclosure without departing from the spirit and scope of the present disclosure. Thus the present disclosure is also intended to encompass these modifications and variations therein as long as these modifications and variations to the present disclosure come into the scope of the claims of the present disclosure and their equivalent technologies.

1. A display panel, comprising:
a base substrate;
a plurality of light-emitting devices on a side of the base substrate; wherein a surface of the light-emitting device facing the base substrate is a light exiting surface of the light-emitting device; and
a driving circuit layer between the base substrate and the plurality of light-emitting devices; wherein, in an area corresponding to a light-emitting area of the light-emitting device, the driving circuit layer comprises: a light-transmitting portion; the light-transmitting portion comprises a low-refractive-index light-transmitting insulating layer and a high-refractive-index light-transmitting insulating layer that are alternately stacked; and a refractive index of the low-refractive-index light-transmitting insulating layer is smaller than a refractive index of the high-refractive-index light-transmitting insulating layer.

2. The display panel according to claim 1, wherein a difference between the refractive indexes of the low-refractive-index light-transmitting insulating layer and the high-refractive-index light-transmitting insulating layer which are adjacent is greater than 0.2.

3. The display panel according to claim 1, wherein the base substrate is adjacent to the low-refractive-index light-transmitting insulating layer; and
the refractive index of the low-refractive-index light-transmitting insulating layer adjacent to the base substrate is smaller than a refractive index of the base substrate.

4. The display panel according to claim 1, wherein the driving circuit layer further comprises: a thin film transistor; and the thin film transistor comprises: a gate electrode, and a source electrode and a drain electrode on a side of the gate electrode facing away from the base substrate;
wherein the light-transmitting portion comprises: a buffer layer between the base substrate and the gate electrode; a first insulating layer between the gate electrode and the source electrode; and a second insulating layer on a side, facing away from the base substrate, of the source electrode and the drain electrode;
wherein a refractive index of the first insulating layer is greater than a refractive index of the buffer layer, and the refractive index of the first insulating layer is greater than a refractive index of the second insulating layer.

5. The display panel according to claim 4, wherein the refractive index of the buffer layer is equal to the refractive index of the second insulating layer.

6. The display panel according to claim 4, wherein a thickness of the first insulating layer is greater than a thickness of the buffer layer; and
the thickness of the first insulating layer is greater than a thickness of the second insulating layer.

7. The display panel according to claim 6, wherein the thickness of the buffer layer is equal to the thickness of the second insulating layer.

8. The display panel according to claim 4, wherein the first insulating layer, the buffer layer and the second insulating layer comprise a same material.

9. The display panel according to claim 1, wherein the base substrate further comprises:
a planarization layer between the plurality of light-emitting devices and the driving circuit layer;
wherein the planarization layer comprises: a light-transmitting material, and scattering particles dispersed in the light-transmitting material.

10. The display panel according to claim 9, wherein a mass fraction of the scattering particles is greater than or equal to 5% and less than or equal to 10%.

11. A method of manufacturing a display panel, comprising:
forming a driving circuit layer on a side of the base substrate; wherein the driving circuit layer comprises: a light-transmitting portion; the light-transmitting portion comprises a low-refractive-index light-transmitting insulating layer and a high-refractive-index light-transmitting insulating layer that are alternately stacked; and a refractive index of the low-refractive-index light-transmitting insulating layer is smaller than a refractive index of the high-refractive-index light-transmitting insulating layer; and
forming a plurality of light-emitting devices on a side of the driving circuit layer facing away from the base substrate; wherein a surface of the light-emitting device facing the base substrate is a light exiting surface of the light-emitting device; and the light-transmitting portion corresponds to a light-emitting area of the light-emitting device.

12. The method according to claim 11, wherein the forming the driving circuit layer on the side of the base substrate, specifically comprises:
forming a buffer layer on the side of the base substrate; wherein a refractive index of the buffer layer is smaller than a refractive index of the base substrate;
forming a first insulating layer on a side of the buffer layer facing away from the base substrate; wherein a refractive index of the first insulating layer is greater than the refractive index of the buffer layer; and
forming a second insulating layer on a side of the first insulating layer facing away from the base substrate; wherein a refractive index of the second insulating layer is smaller than the refractive index of the first insulating layer.

13. The method according to claim 12, wherein the forming the buffer layer on the side of the base substrate, specifically comprises:
forming silicon oxide as the buffer layer on the side of the base substrate by using a chemical vapor deposition process under a condition that a ratio of silane to nitrous oxide is a first preset ratio;
wherein the forming the first insulating layer on the side of the buffer layer facing away from the base substrate, specifically comprises:
forming silicon oxide as the first insulating layer on the side of the buffer layer facing away from the base substrate by using the chemical vapor deposition process under a condition that a ratio of silane to nitrous oxide is a second preset ratio; wherein the first preset ratio is greater than the second preset ratio;
wherein the forming the second insulating layer on the side of the first insulating layer facing away from the base substrate, specifically comprises:
forming silicon oxide as the second insulating layer on the side of the first insulating layer facing away from the base substrate by using the chemical vapor deposition process under the condition that the ratio of silane to nitrous oxide is the first preset ratio.

14. The method according to claim 11, wherein before forming the plurality of light-emitting devices, the method further comprises:
forming a planarization layer on the side of the driving circuit layer facing away from the base substrate;
wherein the planarization layer comprises: a light-transmitting material, and scattering particles dispersed in the light-transmitting material.

15. A display apparatus, comprising the display panel according to claim 1.
